(19) United States
(12) Patent Application Publication
(10) Pub. No.: US 2010/0127260 A1
(43) Pub. Date: May 27, 2010

(54) Antireflection film, antireflection film manufacturing method, and semiconductor device using the antireflection film

(75) Inventor: Eiji Matsuyama, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/591,401

(22) Filed: Nov. 18, 2009

(30) Foreign Application Priority Data
Nov. 26, 2008 (JP) 300324/2008

(51) Int. Cl. H01L 31/0256; H01L 31/08; H01L 31/18

(52) U.S. Cl. 257/49; 257/437; 438/72; 257/E31.003; 257/E31.119; 257/E31.052

(57) ABSTRACT

To improve a transmission rate of an antireflection film, the antireflection film includes: a first silicon oxide film (2), which is formed on a silicon substrate (1); a polysilicon film (3), which is formed on the first silicon oxide film (2) to a thickness of 6 nm through 14 nm; and a second silicon oxide film (4), which is formed on the polysilicon film (3). The transmission rate of the antireflection film is further improved if a thickness of the first silicon oxide film (2) is set to 14 nm through 35 nm. When used in a photoelectric conversion element for such as a solid state image sensor and a photovoltaic generator, the antireflection film may enhance efficiency of photoelectric conversion.

### CROSS-REFERENCE TO RELATED APPLICATIONS

This application is based upon, claims the benefit of priority of, and incorporates by reference the contents of Japanese Patent Application No. 2008-300324 filed on Nov. 26, 2008.

### BACKGROUND

1. Field of the Invention

The present invention relates to an antireflection film, an antireflection film manufacturing method, and a semiconductor device using the antireflection film.

2. Description of Related Art

Forming an antireflection film on a silicon substrate (hereinafter referred to as Si substrate) is a technique utilized in solid state image sensors, photovoltaic generators, semiconductor lithography, and various other fields. In a p-n junction photodiode formed on a Si substrate by ion implantation or other methods, incident light is converted into electrons within the photodiode and accumulated as electrons. If the interface of the Si substrate constituting a part of the p-n junction photodiode is covered with a single-layer film of silicon oxide, silicon nitride, or the like, the large difference in refractive index between the Si substrate and the silicon oxide film or the like increases the reflectance at the Si substrate interface. Consequently, incident light does not enter the interior of the p-n junction photodiode efficiently, thus lowering the sensitivity of the photodiode.

A solution to this problem is to form a multilayer film having different refractive indices at the interface of the Si substrate. This technique may keep the reflectance at the interface between the multilayer film and the Si substrate low and accordingly reduce the loss of incident light. Forming a silicon nitride film or the like as an antireflection film that has a multilayer structure is a widely used technique. With this antireflection film, the lowering in reflectance at the Si substrate interface results in an approximately 18% improvement in sensitivity of a p-n junction photodiode formed by ion implantation or the like on a Si substrate. For more efficient conversion of light into electrons, the reflectance at the Si substrate interface has to be close to 0%, and an improved antireflection film is demanded.

Japanese Unexamined Patent Application Publication (JP-A) No. 2008-27980 A (hereinafter referred to as Reference 1) discloses a technique in which a polysilicon film is used instead of a silicon nitride film (Si₃N₄ film) as an antireflection film for a solid state image sensor. A partial sectional view of this solid state image sensor 100 is illustrated in FIG. 17. The solid state image sensor 100 includes a Si substrate 111, a photodiode 112, a silicon oxide film 113, a gate electrode 114, an insulating film 115, an interlayer insulating film 116, a light-shielding film 117, an insulating film 118, and a microlens 119. The solid state image sensor 100 also includes a polysilicon film 120, which functions as an antireflection film.

In Reference 1, a polysilicon film is used because, while Si₃N₄ has a refractive index n of 2.0, a refractive index of polysilicon is close to a refractive index n of silicon, which is 3.7 to 5.6. Also, compared to a reflected wave at the interface of an Si₃N₄ film or a silicon oxynitride film (SiON film) as an antireflection film, a reflected wave at the interface of a polysilicon film as an antireflection film has an amplitude closer to that of a reflected wave at the interface of a Si substrate. Reference 1 also states that setting the thickness of the polysilicon film to a quarter of a wave length λ of incident light prevents reflection at the interface between the Si substrate and a silicon oxide film, and thus enhances the effect of the polysilicon film as an antireflection film. The reflectance is accordingly lower when the antireflection film employed is a polysilicon film than when the antireflection film is an Si₃N₄ film or an SiON film. This is another reason that a polysilicon film is used in Reference 1.

However, the inventor of the present invention has conducted a detailed examination of these related art examples as follows and has found out that even the antireflection film of Reference 1 has room for improvement.

First, the light absorption in relation to the wave length (spectral sensitivity) of a p-n junction photodiode that converts light into electrons alone is described below. This p-n junction photodiode is formed by implanting ions in silicon. Given below is the light absorption in relation to the wave length (spectral sensitivity) of silicon alone.

I(λ)=I₀exp(−X/L(λ)) Expression 1

S(λ)=I₀exp(−Xₛₜₐᵣₜ/L(λ))−I₀exp(−X_{end}/L(λ))/I₀×100 (%) Expression 2

L(λ)=1/α(λ) Expression 3

α(λ)=a₀·(hc/λ−1.10)^{k} (cm⁻¹) Expression 4

In the expressions, I(λ) represents the attenuation in light intensity at a wave length of λ, L(λ) represents the absorption length at a wave length of λ, S(λ) represents the sensitivity at a wave length of λ, α(λ) represents the silicon absorption coefficient at a wave length of λ, Xₛₜₐᵣₜ represents the start point of light absorption in a depth direction, X_{end} represents the end point of light absorption in the depth direction, h represents Planck's constant, c represents the speed of light in vacuum, I₀ represents the amplitude of light, a₀ represents the silicon absorption coefficient, and k represents the extinction coefficient.

Presented next are the results of simulating the transmission rate characteristics and spectral sensitivity characteristics of various antireflection films in relation to the wave length of incident light.

(1) Si substrate/SiO₂ structure

FIG. 11 illustrates the light transmission rate characteristics of a Si substrate/SiO₂ structure. Layer I is an air layer (refractive index n0=1). Layer II is a first SiO₂ film (refractive index n1=1.48, film thickness d1=3,000 nm). Layer V is a Si substrate (refractive index n4=3.7 to 5.6).

According to FIG. 11, the transmission rate in a wave length range where the silicon absorption rate is high (400 nm to 700 nm) averages 70% to 80%.

FIG. 12 illustrates the spectral sensitivity characteristics of a photodiode having the Si substrate/SiO₂ structure (i.e., a structure in which an SiO₂ film is formed on a surface of a p-n junction photodiode that is formed in a Si substrate). In FIG. 12, the broken line indicates the spectral sensitivity characteristics (simulation result) in an ideal state where the reflectance is zero, the thin solid line indicates the spectral sensitivity characteristics (simulation result) simulated with the light reflectance in the Si substrate/SiO₂ structure taken into account, and the thick solid line indicates the spectral sensitivity characteristics (measured value, the axis of ordinate represents Vout (mV)) of a measurement sample of the Si substrate/SiO₂ structure. Small surges between wave lengths are due to the influence of multiple interference between the SiO₂ films.

(2) Antireflection film A having a three-layer structure (second layer: Si₃N₄ film)

FIG. 13 illustrates the transmission rate characteristics of an antireflection film A having a three-layer structure the second layer of which is an Si₃N₄ film. Layer I is an air layer (refractive index n0=1). Layer II is an SiO₂ film (refractive index n1=1.48, film thickness d1=3,000 nm) that serves as the first layer of the antireflection film. Layer III is the Si₃N₄ film (refractive index n2=2.0, film thickness d2=50 nm) constituting the second layer of the antireflection film. Layer IV is a SiO₂ film (refractive index n3=1.48, film thickness d3=20 nm) that serves as the third layer of the antireflection film. Layer V is a Si substrate (refractive index n4=3.7 to 5.6).

According to FIG. 13, the light transmission rate in a wave length range where the silicon absorption rate is high (400 nm to 700 nm) averages 80% to 90%.

The thin solid line in FIG. 14 indicates the spectral sensitivity characteristics (simulation result) of a p-n junction photodiode that is covered with the three-layer structure antireflection film A (second layer: Si₃N₄ film) . For comparison, FIG. 14 includes the broken line and thick solid line illustrated in FIG. 12. The broken line indicates the spectral sensitivity characteristics (simulation result) in an ideal state where the reflectance is zero, and the thick solid line indicates the spectral sensitivity characteristics (measured value, the axis of ordinate represents Vout (mV)) of a measurement sample of the Si substrate/SiO₂ structure. According to FIG. 14, the sensitivity of the three-layer structure antireflection film A compared to that of the Si substrate/SiO₂ structure is improved by approximately 18%.

(3) Antireflection film B having a three-layer structure (second layer: polysilicon film with thickness (d2) of 15 nm)

FIG. 15 illustrates the transmission rate characteristics of an antireflection film B having a three-layer structure the second layer of which is a polysilicon film with a thickness (d2) of 15 nm. Layer I is an air layer (refractive index n0=1). Layer II is an SiO₂ film (refractive index n1=1.48, film thickness d1=3,000 nm) that serves as the first layer of the antireflection film. Layer III is the polysilicon film (refractive index n2=4.3, film thickness d2=15 nm) constituting the second layer of the antireflection film. Layer IV is an SiO₂ film (refractive index n3=1.48, film thickness d3=20 nm) that serves as the third layer of the antireflection film.

Layer V is a Si substrate (refractive index n4=3.7 to 5.6).

According to FIG. 15, the light transmission rate in a wave length range where the silicon absorption rate is high (400 nm to 700 nm) averages 80% to 90%. The light transmission rate in a wave length range of 400 nm to 500 nm, however, is lowered.

The thin solid line in FIG. 16 indicates the spectral sensitivity characteristics (simulation result) of a p-n junction photodiode that is covered with the three-layer structure antireflection film B (second layer: polysilicon film with thickness (d2) of 15 nm). For comparison, FIG. 16 includes the broken line and thick solid line illustrated in FIG. 12. The broken line indicates the spectral sensitivity characteristics (simulation result) in an ideal state where the reflectance is zero, and the thick solid line indicates the spectral sensitivity characteristics (measured value, the axis of ordinate represents Vout (mV)) of a measurement sample of the Si substrate/SiO₂ structure. As can be seen in FIG. 16, the simulation result has revealed that the polysilicon film constituting the second layer of the three-layer structure antireflection film B causes absorption (lowering in sensitivity to blue) in a wave length range of 400 nm to 500 nm, which leads to a lowered spectral sensitivity in the wave length range of 400 nm to 500 nm.

It is thus found out that the polysilicon film of Reference 1 (film thickness: 15 nm to 60 nm) does not make an effective antireflection film because of the light absorption by the polysilicon film which lowers the sensitivity in the wave length range of 400 nm to 500 nm.

### SUMMARY

In one aspect of the present invention, there is provided an antireflection film including: a first silicon oxide film which is formed on a semiconductor substrate; a polysilicon film which is formed on the first silicon oxide film and which has a thickness of 6 nm through 14 nm; and a second silicon oxide film which is formed on the polysilicon film.

In another aspect of the present invention, there is provided an antireflection film manufacturing method including: forming a first silicon oxide film on a semiconductor substrate; forming a polysilicon film on the first silicon oxide film to a thickness of 6 nm through 14 nm; and forming a second silicon oxide film on the polysilicon film.

An antireflection film that has the three-layer structure described above may reduce light absorption in the polysilicon film. Accordingly, it is possible to provide an antireflection film high in transmission rate.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a partial sectional view illustrating a layer structure of an antireflection film according to an embodiment of the present invention;

FIG. 2 is a graph illustrating transmission rate characteristics of the antireflection film according to the embodiment of the present invention;

FIG. 3 is a graph illustrating spectral sensitivity characteristics of a photodiode that has the antireflection film according to the embodiment of the present invention;

FIG. 4 is a graph illustrating light absorption characteristics in a three-layer structure antireflection film that uses a polysilicon film as its second layer;

FIG. 5 is a graph plotting relation between a ratio at which incident light having a wave length of 400 nm to 500 nm is absorbed in a polysilicon film that constitutes a second layer of an antireflection film and a thickness of the polysilicon film;

FIG. 6 is a graph illustrating relation between the transmission rate of the antireflection film according to the embodiment of the present invention and the thickness of the polysilicon film that constitutes the second layer of the antireflection film;

FIG. 7 is a graph illustrating relation between a thickness of a third layer (silicon oxide film) of the antireflection film according to the embodiment of the present invention and the transmission rate of the antireflection film;

FIG. 8 is a table comparing sensitivities of the antireflection film according to the embodiment of the present invention against sensitivities of an antireflection film that has a different structure;

FIG. 9 is a partial sectional view of a solid state image sensor that uses the antireflection film according to the embodiment of the present invention;

FIG. 10A is a partial sectional view of a photovoltaic generator that uses the antireflection film according to the embodiment of the present invention;

FIG. 10B is a partial sectional view of another photovoltaic generator that uses the antireflection film according to the embodiment of the present invention;

FIG. 11 is a graph illustrating transmission rate characteristics of a Si substrate/SiO₂ structure;

FIG. 12 is a graph illustrating spectral sensitivity characteristics of a photodiode that has the Si substrate/SiO₂ structure;

FIG. 13 is a graph illustrating transmission rate characteristics of a three-layer structure antireflection film the second layer of which is an Si₃N₄ film;

FIG. 14 is a graph illustrating spectral sensitivity characteristics of a photodiode that uses the three-layer structure antireflection film the second layer of which is the Si₃N₄ film;

FIG. 15 is a graph illustrating transmission rate characteristics of a three-layer structure antireflection film the second layer of which is a polysilicon film with a thickness of 15 nm;

FIG. 16 is a graph illustrating spectral sensitivity characteristics of a photodiode that uses the three-layer structure antireflection film the second layer of which is the polysilicon film with a thickness of 15 nm; and

FIG. 17 is a partial sectional view of a solid state image sensor disclosed in Reference 1.

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated for explanatory purposes.

An embodiment of the present invention will be described below with reference to the drawings.

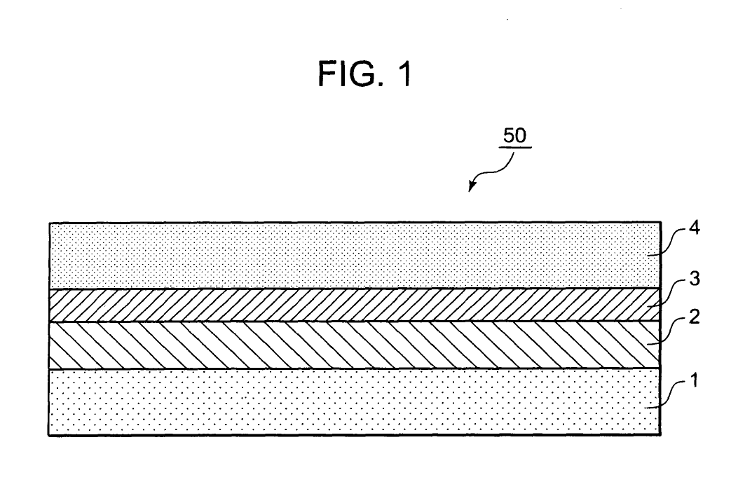

FIG. 1 is a partial sectional view illustrating a layer structure of an antireflection film 50 according to the embodiment of the present invention. The antireflection film 50 includes: a first silicon oxide film 2, which is formed on a Si substrate 1; a polysilicon film 3, which is formed on the first silicon oxide film 2 to a thickness of 6 nm through 14 nm; and a second silicon oxide film 4, which is formed on the polysilicon film 3.

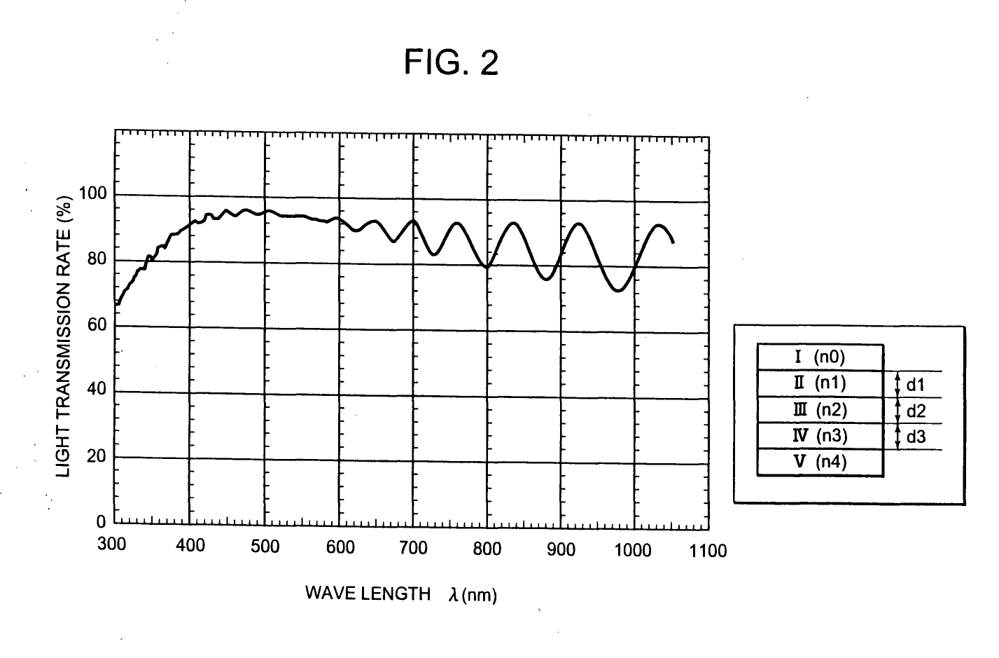

FIG. 2 is a graph illustrating transmission rate characteristics of the antireflection film 50 according to the embodiment of the present invention. This antireflection film 50 has a three-layer structure, and a second layer of the antireflection film 50 is a polysilicon film. Layer I is an air layer (refractive index n0=1). Layer II is the SiO₂ film (refractive index n1=1.48, film thickness d1=3,000 nm, also referred to as second silicon oxide film) that serves as a first layer of the antireflection film 50. Layer III is the polysilicon film (refractive index n2=4.3, film thickness d2=10 nm) constituting the second layer of the antireflection film 50. Layer IV is the SiO₂ film (refractive index n3=1.48, film thickness d3=20 nm, also referred to as first silicon oxide film) that serves as a third layer of the antireflection film 50. Layer V is the Si substrate (refractive index n4=3.7 to 5.6).

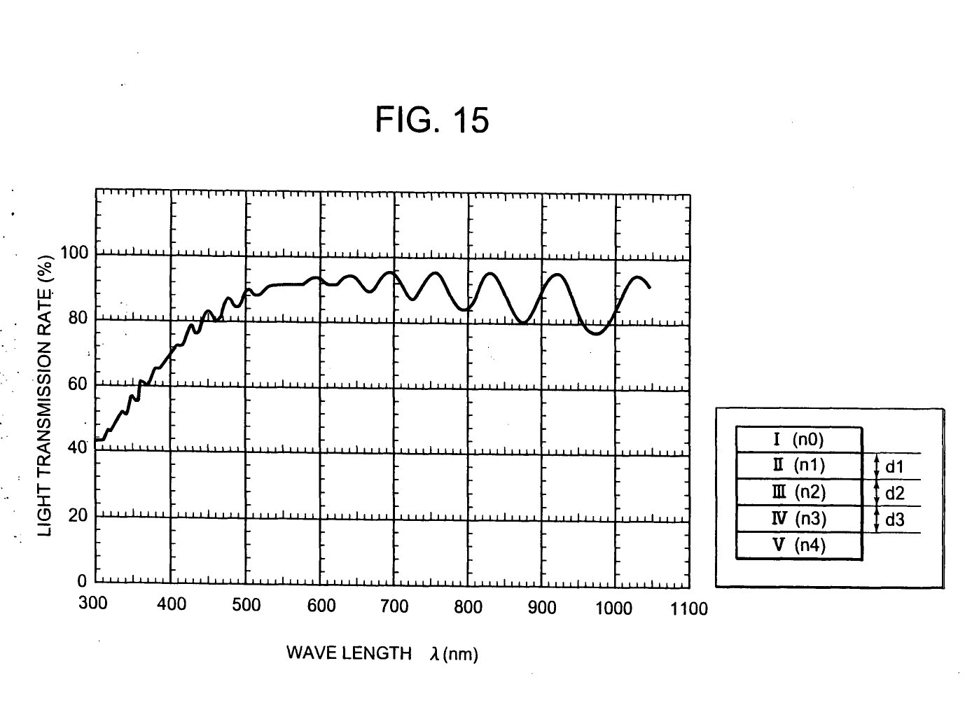

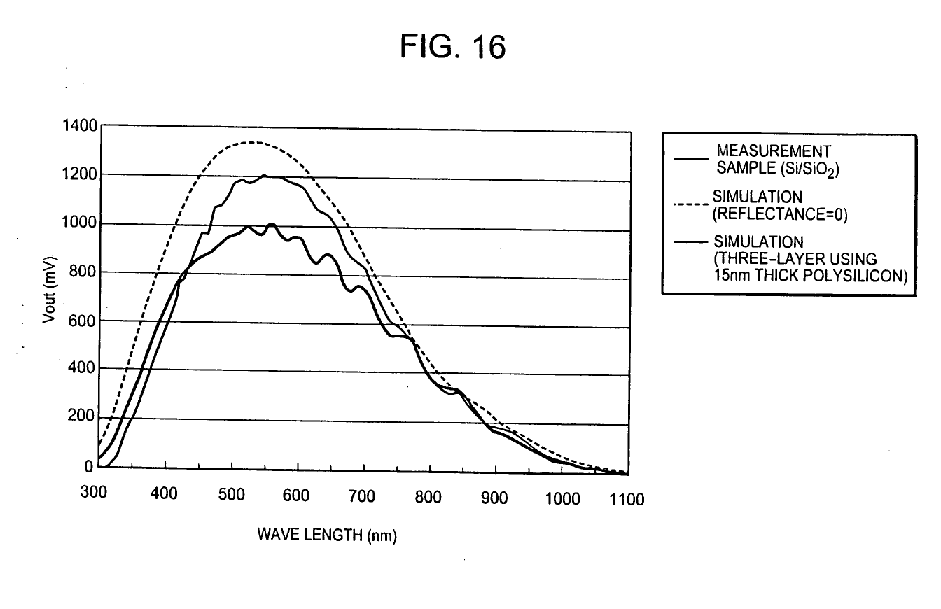

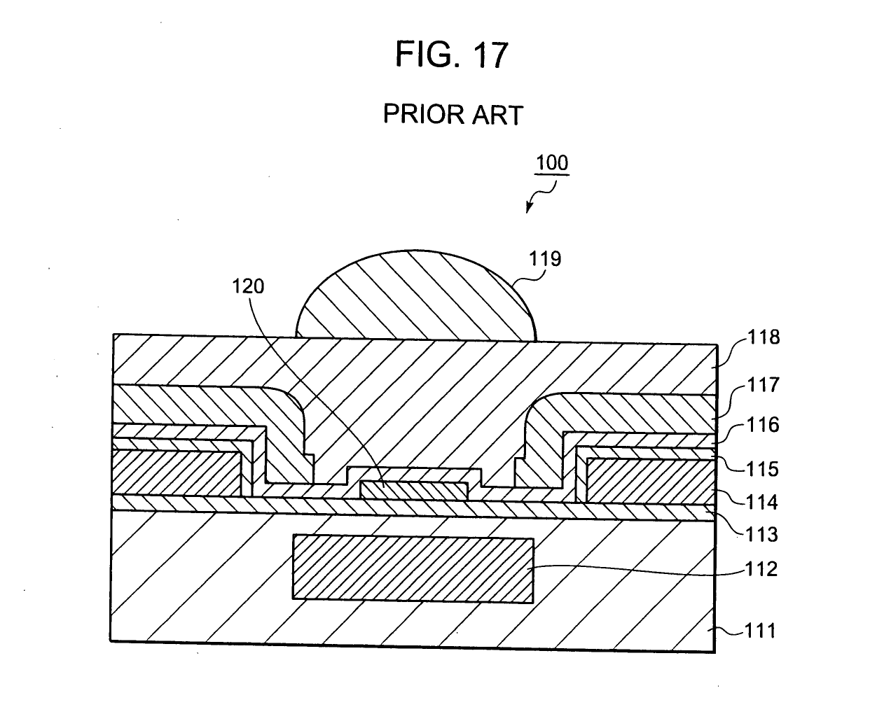

According to FIG. 2, a light transmission rate in a wave length range where a silicon absorption rate is high (400 nm to 700 nm) averages 90% to 95%. In particular, the transmission rate of the antireflection film 50 of this embodiment in a wave length range of 400 nm to 500 nm is higher than that of the three-layer structure antireflection film B illustrated in FIG. 15 which has a polysilicon film with a thickness (d2) of 15 nm as its second layer.

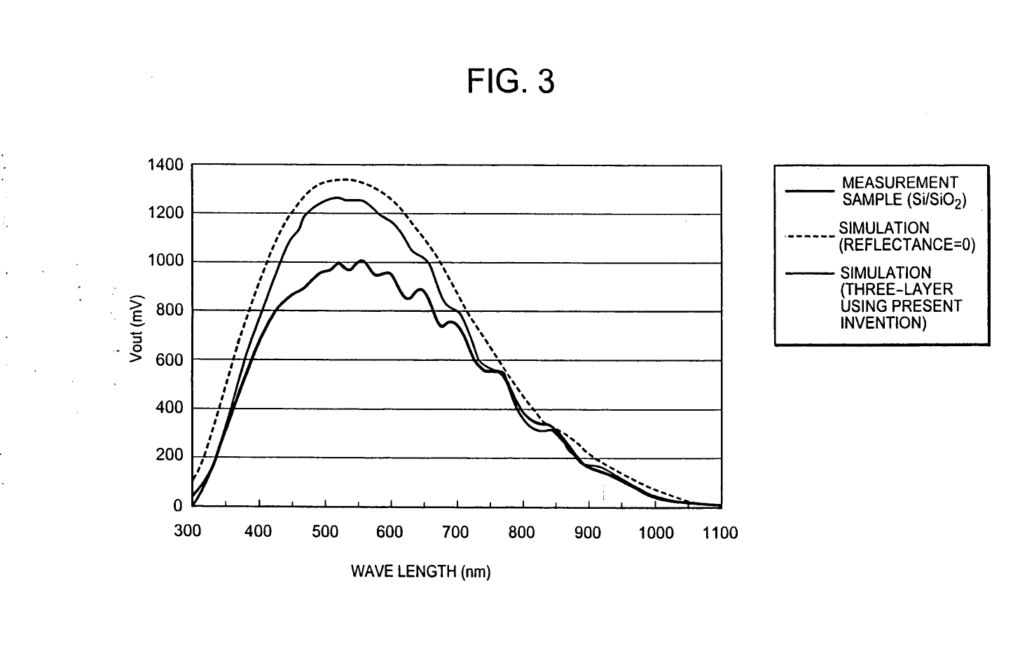

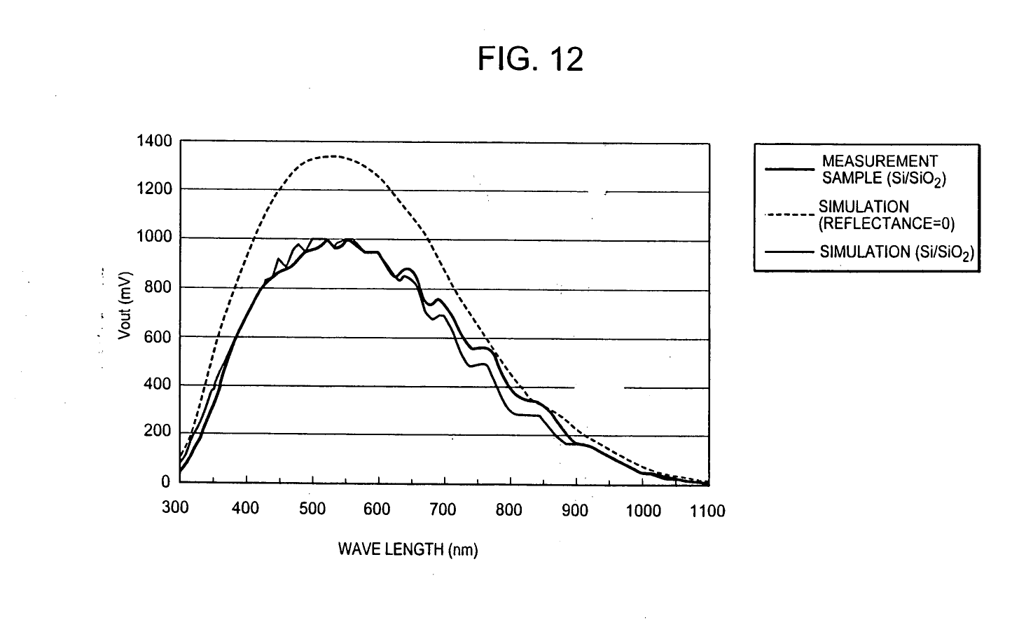

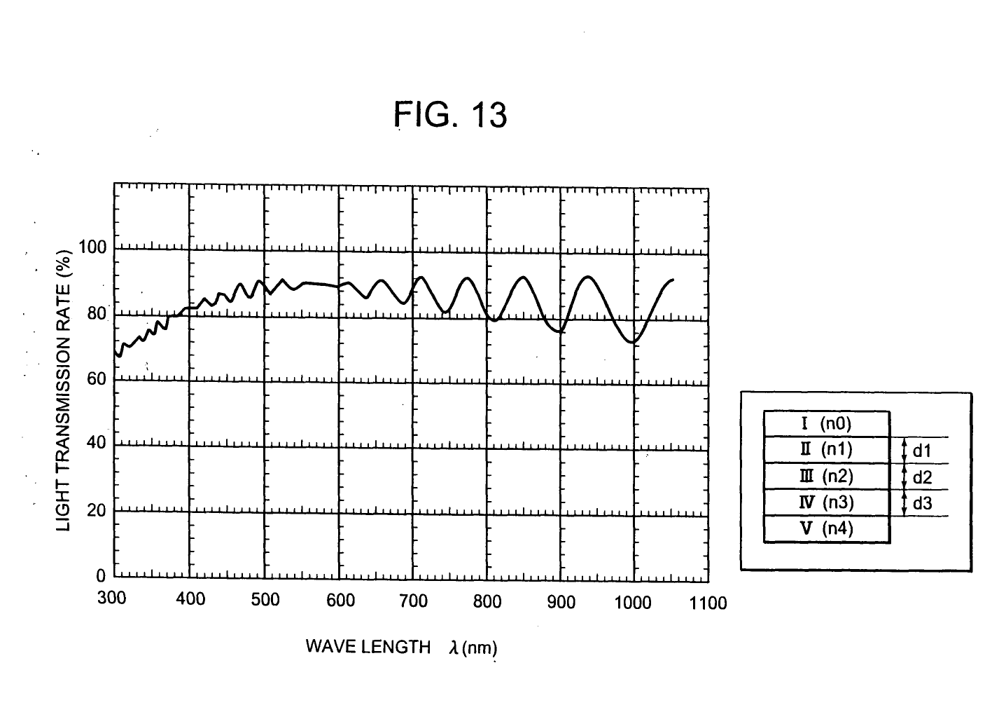

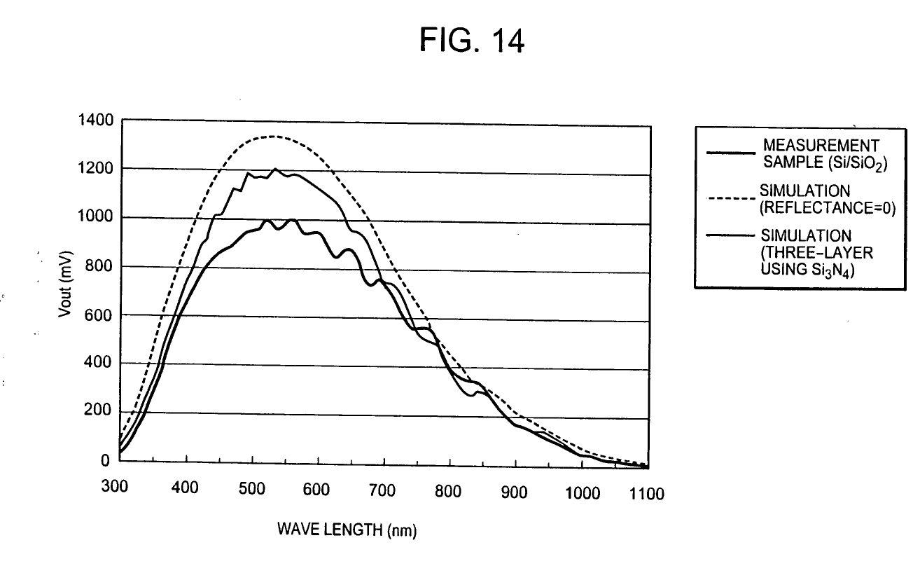

Spectral sensitivity characteristics (simulation result) of a photodiode that has the antireflection film 50 according to this embodiment are indicated by the thin solid line in FIG. 3. For comparison, FIG. 3 includes the broken line and thick solid line illustrated in FIG. 12. The broken line indicates the spectral sensitivity characteristics (simulation result) in an ideal state where the reflectance is zero, and the thick solid line indicates the spectral sensitivity characteristics (measured value, the axis of ordinate represents Vout (mV)) of a measurement sample of the Si substrate/SiO₂ structure.

The inventor of the present invention have examined light absorption characteristics of the three-layer structure antireflection film according to this embodiment while varying the thickness of the polysilicon film which constitutes the second layer. A complex refraction index N is expressed as N=(n−ik), an absorption coefficient a is expressed as α=4πk/λ, and k in the complex refraction index of silicon is not zero (k≠0) . The antireflection film therefore has characteristics that cause light to be absorbed when transmitted through the antireflection film.

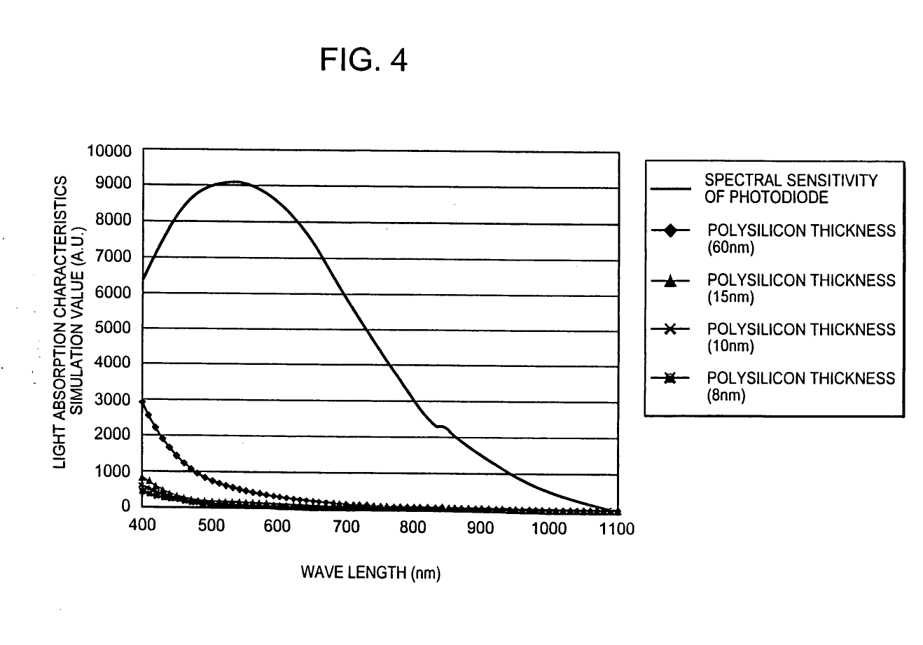

FIG. 4 is a graph illustrating the light absorption characteristics (simulation result) of a three-layer structure antireflection film (the thickness of the polysilicon film constituting the second layer is 8 nm to 60 nm) with respect to incident light that has a wave length of 400 nm to 1,100 nm. The thick solid line in FIG. 4 indicates the spectral sensitivity characteristics (simulation result) of a p-n junction photodiode.

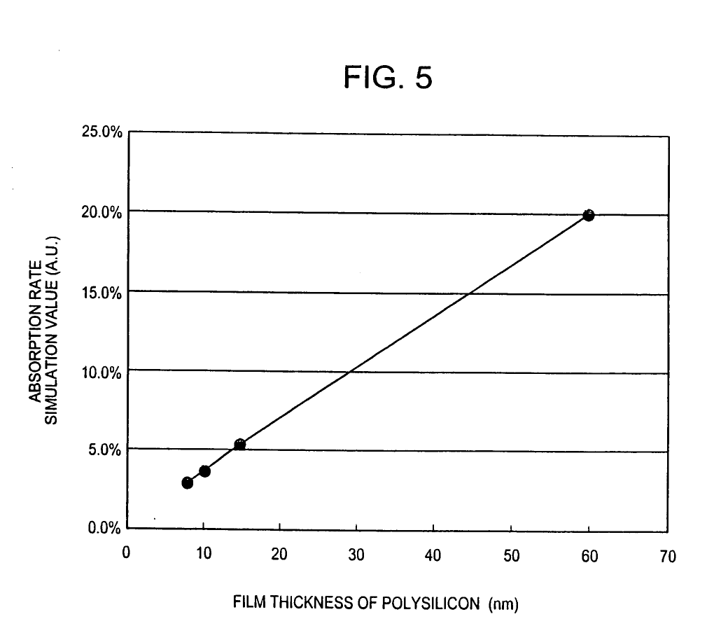

FIG. 5 is a graph plotting a light absorption rate at which incident light having a wave length of 400 nm to 500 nm is absorbed in relation to the thickness of the polysilicon film constituting the second layer (8 nm to 60 nm). This is calculated from the spectral sensitivity characteristics of the photodiode in FIG. and from the light absorption characteristics of the three-layer structure antireflection film (the thickness of the polysilicon film constituting the second layer is 8 nm to 60 nm). It is understood from FIG. 5 that the polysilicon film constituting the second layer of the antireflection film absorbs 5% or more of incident light when the polysilicon film is thicker than 15 nm.

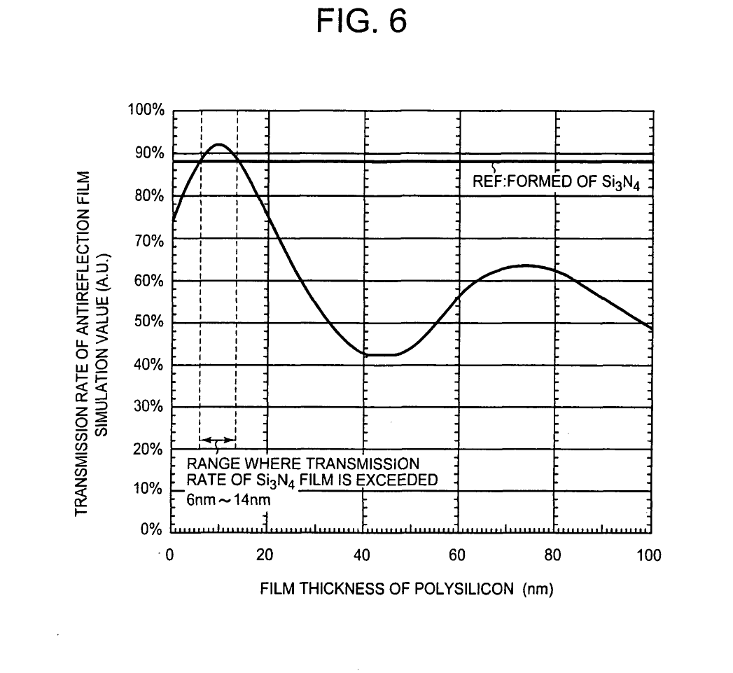

FIG. 6 is a graph illustrating the transmission rate (simulation result) of the three-layer structure antireflection film according to this embodiment in relation to the varied thickness of the polysilicon film which constitutes the second layer. In this case, the first silicon oxide film 2 (the third layer of the antireflection film) which is Layer IV has a thickness of 20 nm. The axis of ordinate represents the transmission rate (%) of the antireflection film, and the axis of abscissa represents the thickness of the polysilicon film which constitutes the second layer of the antireflection film. It is understood from FIG. 6 that the transmission rate of the antireflection film declines when the thickness of the polysilicon film in the three-layer structure antireflection film is smaller than 6 nm.

FIG. 6 also illustrates that, when the polysilicon film in the three-layer structure antireflection film is 6 nm to 14 nm in thickness, the sum of transmission rates in an absorption range of the photodiode (wave length of incident light: 300 nm to 1,100 nm) is larger than in the case where the antireflection film A (second layer: Si₃N₄ film) is employed. It is therefore concluded that setting the thickness of the polysilicon film that constitutes the second layer to 6 nm to 14 nm makes the antireflection film more efficient (higher in transmission rate).

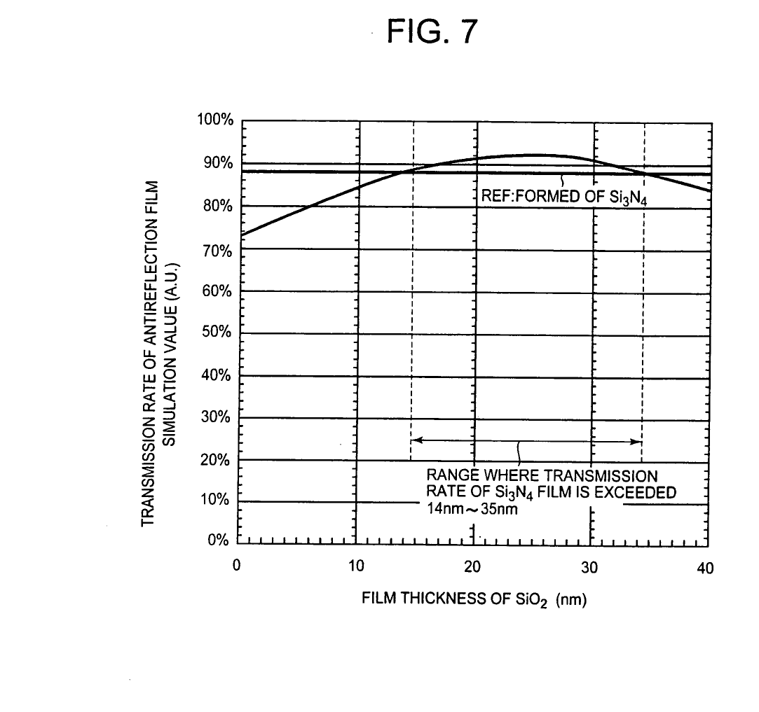

FIG. 7 illustrates the transmission rate (simulation result) of the antireflection film 50 according to this embodiment in relation to the varied thickness of the SiO₂ film that constitutes the third layer. In this case, the polysilicon film constituting the second layer of the antireflection film 50 is 10 nm in thickness. In FIG. 7, the axis of ordinate represents the transmission rate (%) of the antireflection film 50, and the axis of abscissa represents the thickness of the SiO₂ film that constitutes the third layer of the antireflection film 50. FIG. 7 illustrates that, when the SiO₂ film constituting the third layer of the antireflection film 50 is 14 nm to 35 nm in thickness, the sum of transmission rates in the absorption range of the photodiode (wave length of incident light: 300 nm to 1,100 nm) is larger than in the case where the antireflection film A (second layer: Si₃N₄ film) is employed. It is therefore concluded that setting the thickness of the SiO₂ film that constitutes the third layer of the antireflection film 50 to 14 nm to 35 nm makes the antireflection film 50 more efficient (higher in transmission rate).

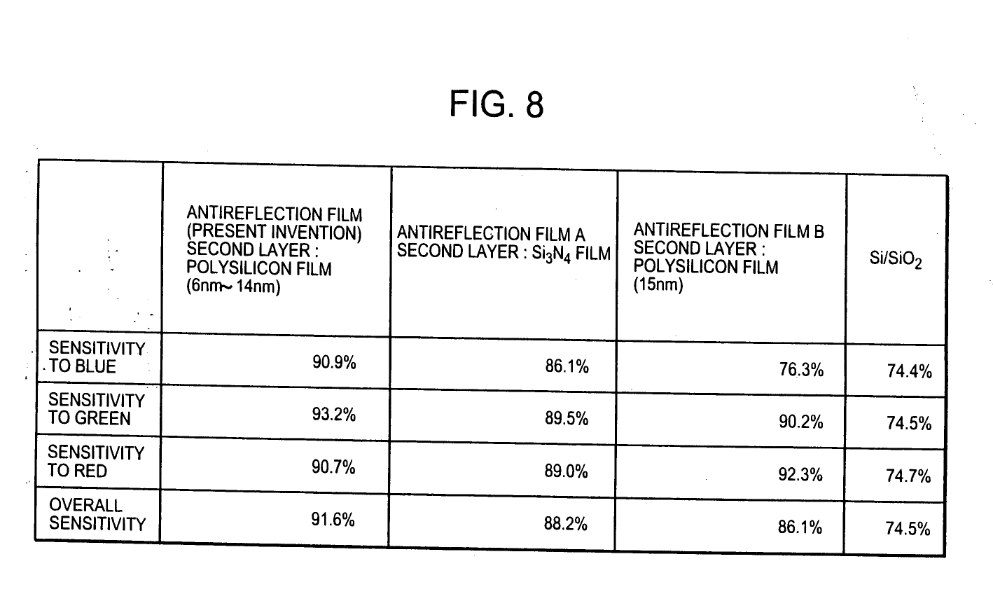

FIG. 8 is a table in which the characteristics of antireflection films having different structures are put together. In the table, “antireflection film (present invention)” refers to the three-layer structure antireflection film 50 according to this embodiment which has a polysilicon film with a thickness of 6 nm through 14 nm as its second layer. “Antireflection film A” refers to the three-layer structure antireflection film A which has an Si₃N₄ film as its second layer. “Antireflection film B” refers to the three-layer structure antireflection film B which has a polysilicon film with a thickness of 15 nm as its second layer. “Si substrate/SiO₂” refers to the structure in which an SiO₂ film is formed on a Si substrate to a thickness of 3,000 nm.

It is understood from this table that, compared to “antireflection film A”, “antireflection film (present invention) ” is improved in sensitivity to blue by 4.8%, improved in sensitivity to green by 3.7%, improved in sensitivity to red by 1.7%, and improved in overall sensitivity by 3.4%. Compared to “antireflection film B”, “antireflection film (present invention)” is improved in sensitivity to blue by 14.6%, improved in sensitivity to green by 3.0%, and improved in overall sensitivity by 5.5%.

As has been described, the antireflection film 50 according to this embodiment includes: the first silicon oxide film 2, which is formed on the Si substrate 1; the polysilicon film 3, which is formed on the first silicon oxide film 2 to a thickness of 6 nm through 14 nm; and the second silicon oxide film 4, which is formed on the polysilicon film 3. The characteristics of the antireflection film 50 is improved even more by setting the thickness of the first silicon oxide film 2 to 14 nm through 35 nm.

Effects of the three-layer structure antireflection film 50 according to this embodiment are described below in a comprehensive manner.

In a wave length range of 400 nm to 500 nm, the transmission rate of the antireflection film 50 according to this embodiment (see FIG. 2) which has a polysilicon film with a thickness of 6 nm through 14 nm as its second layer is higher than the transmission rate of the antireflection film B (see FIG. 15) which has a polysilicon film with a thickness (d2) of 15 nm as its second layer. This is attributable to the fact that the absorption of incident light in the polysilicon film may be reduced to 5% or less by setting the thickness of the polysilicon film to 6 nm through 14 nm (see FIG. 5).

Setting the thickness of the polysilicon film to 6 nm through 14 nm may also make the transmission rate of the antireflection film 50 higher than that of the antireflection film A which has an Si₃N₄ film as its second layer (see FIG. 6).

Compared to the antireflection film A which has the Si₃N₄ film as its second layer, the three-layer structure antireflection film 50 according to this embodiment is improved in sensitivity characteristics by approximately 3.4%. The antireflection film 50 is also improved in sensitivity characteristics by approximately 5.5% from the antireflection film B which has a polysilicon film with a thickness of 15 nm as its second layer (see FIG. 8).

In short, the three-layer structure antireflection film according to this embodiment is improved in transmission rate from the related art by optimizing the amount of light absorbed when incident light is transmitted through the polysilicon film, and optimizing the transmission rate of the antireflection film with respect to light of the respective wave lengths.

A method of manufacturing the antireflection film 50 according to this embodiment is described below. The first silicon oxide film 2 is formed on the Si substrate 1. The polysilicon film 3 is formed on the first silicon oxide film 2 to a thickness of 6 nm through 14 nm. The second silicon oxide film 4 is formed on the polysilicon film 3. The thickness of the first silicon oxide film 2 may be set to 14 nm through 35 nm.

The manufacture of the antireflection film 50 according to this embodiment may use common film formation technologies such as chemical vapor deposition (CVD) and sputtering.

Described next is a semiconductor device that uses an antireflection film according to the present invention.

The semiconductor device that uses an antireflection film according to the present invention has a photoelectric conversion element which converts light into electricity, and an antireflection film placed on a side of the photoelectric conversion element from which light enters the photoelectric conversion element. The use of an antireflection film according to the present invention which is high in transmission rate may improve the conversion efficiency of the photoelectric conversion element.

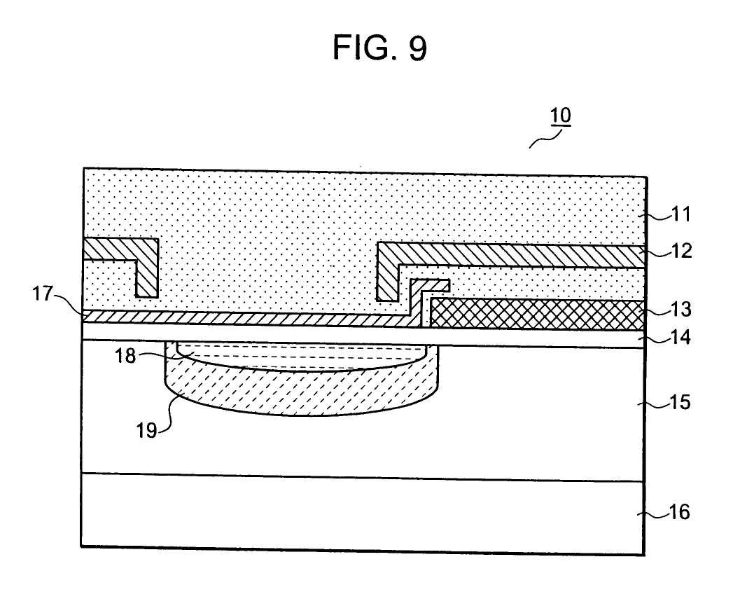

A solid state image sensor 10 is described next with reference to FIG. 9 as an example of the semiconductor device that uses an antireflection film according to the present invention. The photoelectric conversion element of the solid state image sensor 10 is a photo detector cell that includes a Si substrate 16, a P-type well 15, an N-type diffusion layer 19 and a P⁺-type diffusion layer 18, which constitute a photodiode part, a silicon oxide film 14, a gate electrode 13, an interlayer insulating film 11, and a light-shielding film 12. The photo detector cell also includes a polysilicon film 17 placed between the silicon oxide film 14 and the interlayer insulating film 11 in order to reduce reflection loss.

In the solid state image sensor 10, the incidence of light causes the photodiode part to accumulate electric charges, and the antireflection film of the present invention described above is formed on a side of the photodiode part from which light enters. In other words, the silicon oxide film 14, the polysilicon film 17, and the interlayer insulating film 11 are formed on the light incidence side of the photodiode part. The thickness of the polysilicon film 17 is set within a range of 8 nm to 14 nm. The antireflection film may have even more improved characteristics if the silicon oxide film 14 has a thickness of 14 nm to 35 nm.

In short, the solid state image sensor 10 is improved in sensitivity because the reflection of incident light at the interface between the Si substrate and the silicon oxide film 14 is reduced.

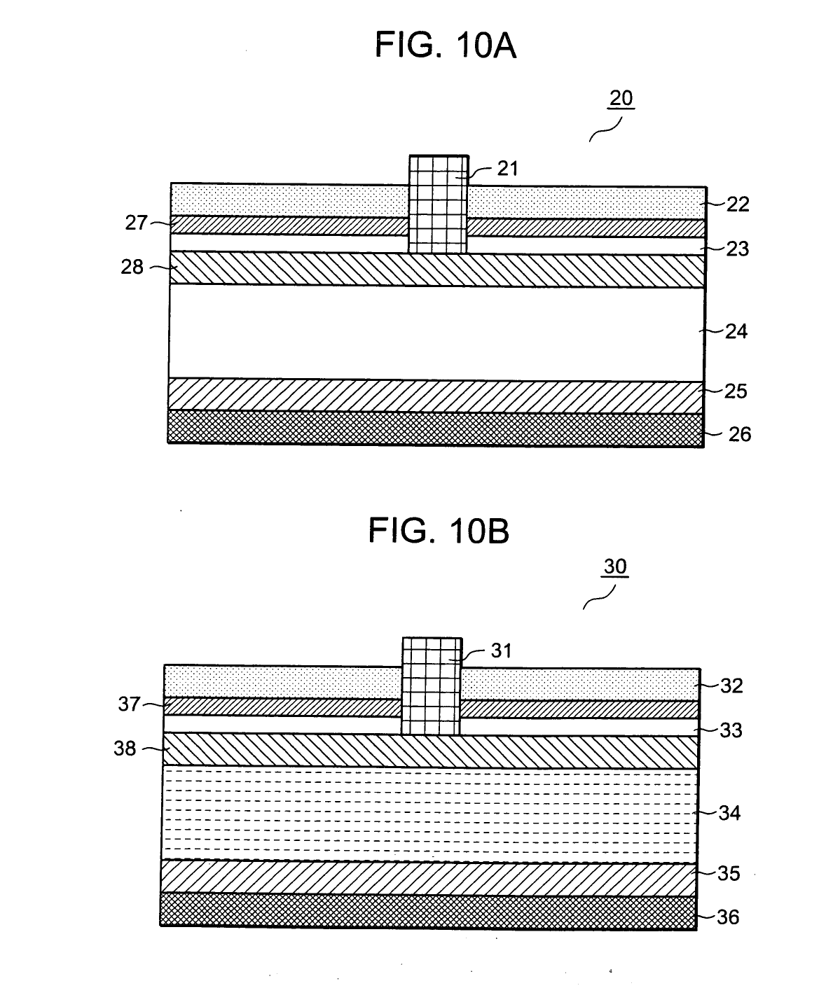

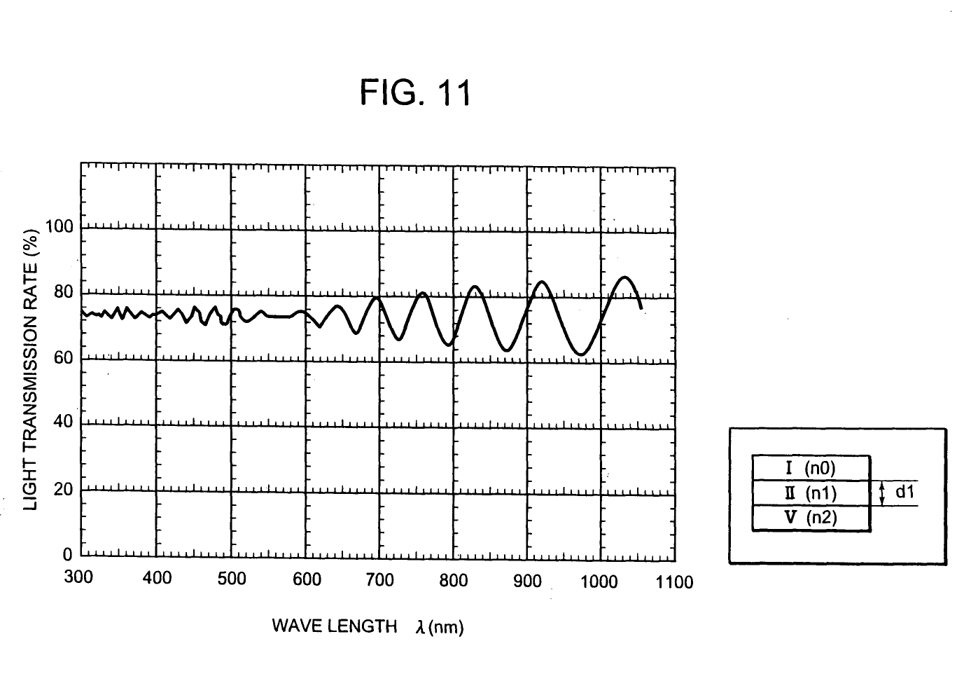

A photovoltaic generator 20 illustrated in FIG. 10A is described next as another example of the semiconductor device that uses an antireflection film according to the present invention.

The photovoltaic generator 20 includes, on the front side of a p-type Si substrate 24, an n⁺-type layer 28 in which phosphorus is diffused and a negative electrode 21. On the rear side of the p-type Si substrate 24, a p⁺-type layer 25 in which boron is diffused is formed and connected to a positive electrode 26. With a photoelectric conversion element (photodiode) that includes a photo detector cell thus structured, electric power may be obtained from light incident upon a surface of the photovoltaic generator 20.

The photovoltaic generator 20 also includes a first silicon oxide film 23, a polysilicon film 27, and a second silicon oxide film 22, which are formed as an antireflection film. This antireflection film used in the photovoltaic generator 20, too, has a three-layer structure as does the antireflection film 50 described above, and may be high in transmission rate and photoelectric conversion efficiency by setting the thicknesses of the three layers in the manner described above about the layers of the antireflection film 50.

The photovoltaic generator 20 which uses an antireflection film according to the present invention is improved in power generation efficiency because the reflection of incident light at the interface between the Si substrate (n⁺-type layer 28) and the silicon oxide film 23 may be reduced.

A photovoltaic generator 30 illustrated in FIG. 10B is described next as still another example of the semiconductor device that uses an antireflection film according to the present invention.

The photovoltaic generator 30 includes, on the front side of an amorphous silicon substrate 34, a p⁺-type layer 38 and a positive electrode 31. On the rear side of the amorphous silicon substrate 34, an n⁺-type layer 35 is formed and connected to a negative electrode 36. With a photoelectric conversion element (photodiode) that includes a photo detector cell thus structured, electric power may be obtained from light incident upon a surface of the photovoltaic generator 30.

The photovoltaic generator 30 also includes a first silicon oxide film 33, a polysilicon film 37, and a second silicon oxide film 32, which are formed as an antireflection film. This antireflection film used in the photovoltaic generator 30, too, has a three-layer structure as does the antireflection film 50 described above, and may be high in transmission rate and photoelectric conversion efficiency by setting the thicknesses of the three layers in the manner described above about the layers of the antireflection film 50.

The photovoltaic generator 30 which uses an antireflection film according to the present invention is improved in power generation efficiency because the reflection of incident light at the interface between the amorphous silicon substrate (p⁺-type layer 38) and the silicon oxide film 33 may be reduced.

Although the invention has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. An antireflection film, comprising:
a first silicon oxide film which is formed on a semiconductor substrate;
a polysilicon film which is formed on the first silicon oxide film and which has a thickness of 6 nm through 14 nm; and
a second silicon oxide film which is formed on the polysilicon film.

2. An antireflection film according to claim 1, wherein the first silicon oxide film has a thickness of 14 nm through 35 nm.

3. A semiconductor device having an antireflection film, comprising a photoelectric conversion element with the antireflection film formed on its surface, the antireflection film comprising the antireflection film according to claim 1.

4. A semiconductor device having an antireflection film according to claim 3, wherein the photoelectric conversion element comprises a photodiode formed in the semiconductor substrate.

5. A semiconductor device having an antireflection film according to claim 4, which is a solid state image sensor comprising the photodiode.

6. A semiconductor device having an antireflection film according to claim 4, which is a photovoltaic generator comprising the photodiode.

7. An antireflection film manufacturing method, comprising:
forming a first silicon oxide film on a semiconductor substrate;
forming a polysilicon film on the first silicon oxide film to a thickness of 6 nm through 14 nm; and
forming a second silicon oxide film on the polysilicon film.

8. An antireflection film manufacturing method according to claim 7, wherein the first silicon oxide film has a thickness of 14 nm through 35 nm.

9. An antireflection film manufacturing method according to claim 8, further comprising forming a p-n junction photodiode by introducing impurities in the semiconductor substrate,
wherein the first silicon oxide film, the polysilicon film, and the second silicon oxide film are formed on a surface of the p-n junction photodiode.
